(19) United States
(12) Patent Application Publication
(10) Pub. No.: US 2023/0373042 A1
(43) Pub. Date: Nov. 23, 2023

(54) SUBSTRATE CHUCK USED IN SCRUBBING PROCESS

(71) Applicant: KCTECH CO., LTD., Anseong-si (KR)

(72) Inventor: Jun Ho SON, Gyeongsan-si (KR)

(73) Assignee: KCTECH CO., LTD., Anseong-si (KR)

(21) Appl. No.: 18/104,592

(22) Filed: Feb. 1, 2023

(30) Foreign Application Priority Data
May 18, 2022 (KR) 10-2022-0061124

(51) Int. Cl. B23Q 3/08

(52) U.S. Cl. CPC B23Q 3/088; B23Q 2703/04; B23Q 2717/00

(57) ABSTRACT

Disclosed is a substrate chuck. More particularly, a substrate chuck including a chucking film made of a flexible material capable of elastic deformation to cover a mounting region of an upper surface of a surface plate on which a substrate is to be mounted; and a substrate chuck for gripping the substrate by applying suction pressure to a lower part of the chucking film to form a vacuum between the chucking film and the substrate; and a substrate scrubbing apparatus including the substrate chuck are provided.

### CROSS-REFERENCE TO RELATED APPLICATIONS

This application claims the benefit of Korean Application No. 10-2022-0061124, filed May 18, 2022, in the Korean Intellectual Property Office. All disclosures of the document named above is incorporated herein by reference.

### TECHNICAL FIELD

The present invention relates to a substrate chuck, and more particularly, to a substrate chuck for preventing liquid from entering the substrate chuck during a substrate scrubbing process.

### BACKGROUND ART

A substrate treatment process may include a process of wiping or finely polishing the surface of a substrate with a rotating pad in a state in which the substrate is fixed to a substrate chuck.

The substrate treatment process involves rubbing a substrate W with a pad 21 of a scrubbing unit 20 in a state in which the substrate W is adsorbed and fixed to a substrate chuck 10 shown in FIGS. 1 and 2.

In the case of an existing substrate chuck 10, a plurality of suction holes 11 to which suction pressure is applied are formed on a substrate-mounting surface 10s and the suction holes 11 are connected to a negative pressure-applying part V through a pneumatic passage 12, so that the substrate W is positioned on and fixed to a mounting surface of the substrate chuck 10 by suction pressure 55 applied by the negative pressure-applying part V.

However, when a substrate treatment process is performed while a liquid material such as a cleaning liquid or a slurry is supplied to the substrate W by a treatment liquid supply part 30, as shown in FIG. 2, the liquid material may penetrate the suction holes 11 in a state in which the substrate W is separated from the mounting surface 10s.

When a liquid material penetrates the suction holes 11, a vacuum pump installed in the negative pressure-applying part V may be out of order. To prevent this, a gas-liquid separator needs to be additionally installed on the substrate chuck 10. The installation of the gas-liquid separator is not preferable because it causes a higher cost in manufacturing the substrate chuck 10.

Therefore, there is an urgent need for a method of being capable of fundamentally preventing the penetration of a liquid material used during a substrate treatment process while securely holding the substrate W.

### DISCLOSURE

### Technical Problem

Therefore, the present invention has been made in view of the above problems, and it is one object of the present invention to provide a substrate chuck configured to prevent a liquid used for a substrate from penetrating the inside of the substrate during a substrate treatment process.

It is another object of the present invention not only to increase the reliability of holding a substrate, but also to reliably separate the substrate from a mounting surface of a substrate chuck.

### Technical Solution

In accordance with an aspect of the present invention, the above and other objects can be accomplished by the provision of a substrate chuck including a chucking film made of a flexible material capable of elastic deformation to cover a mounting region of an upper surface of a surface plate on which a substrate is to be mounted; and a substrate chuck for gripping the substrate by applying suction pressure to a lower part of the chucking film to form a vacuum between the chucking film and the substrate; and a substrate scrubbing apparatus including the substrate chuck.

In the present specification and the accompanying claims, the term “transverse direction” and terms similar thereto are defined to refer to a horizontal direction perpendicular to the direction of gravity.

In the present specification and the accompanying claims, the term “up-down direction” and terms similar thereto are defined to refer to the direction of gravity.

### Advantageous Effects

In accordance with the present invention, the surface of the substrate chuck, on which the substrate is seated, is entirely covered with the chucking film made of a flexible material capable of elastic deformation, and suction pressure is applied to a lower side of the chucking film, thereby forming a vacuum between the chucking film and the substrate to grip the substrate W. Accordingly, a liquid material can be fundamentally prevented from entering the inside of the substrate chuck.

### DESCRIPTION OF DRAWINGS

FIG. 1 is a perspective view illustrating the configuration of a general substrate chuck

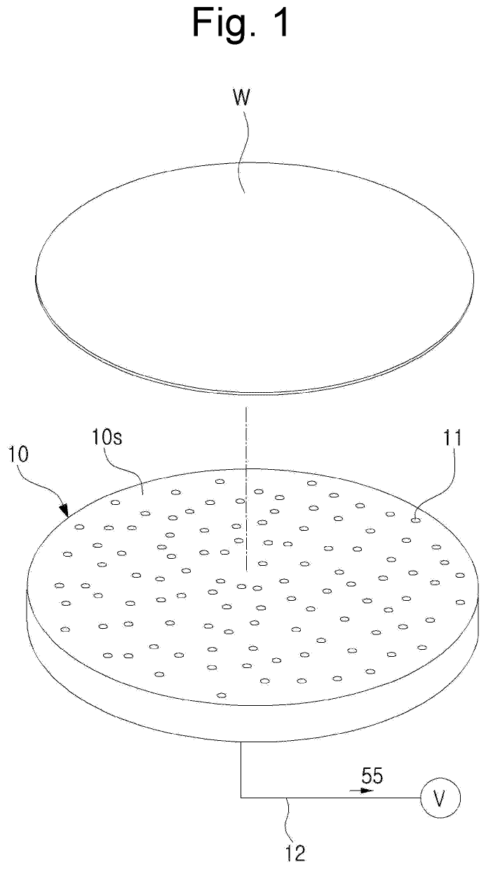

FIG. 2 is a longitudinal sectional view illustrating the configuration of a substrate scrubbing apparatus to which the substrate chuck of FIG. 1 is applied.

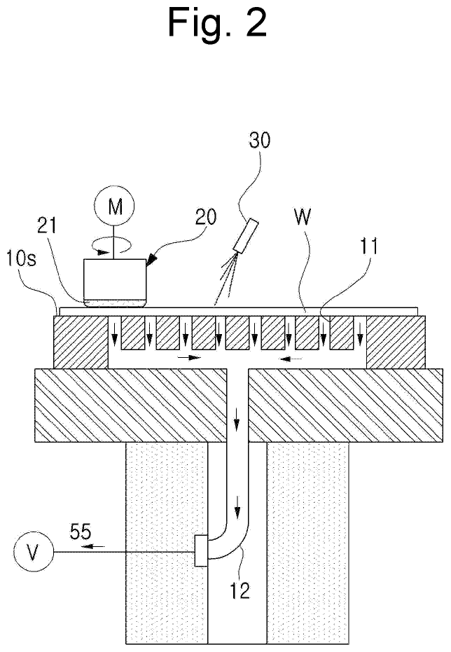

FIG. 3 is a longitudinal sectional view illustrating the configuration of a substrate chuck according to an embodiment of the present invention.

FIG. 4 is a view illustrating a state in which a substrate is mounted on a mounting surface of a substrate chuck of FIG. 3.

FIG. 5 is a view illustrating a state in which the substrate mounted on the mounting surface of the substrate chuck of FIG. 3 is gripped.

FIG. 6 is a view illustrating the configuration of a substrate scrubbing apparatus provided with the substrate chuck of FIG. 3.

FIG. 7 is a view illustrating a configuration of separating the substrate from the substrate chuck after a substrate treatment process is finished.

FIG. 8 illustrates an enlarged view of part ‘A’ in FIG. 5.

FIG. 9A illustrates a cross-sectional view taken along line X-X of FIG. 3.

FIG. 9B illustrates the configuration of another embodiment of the present invention corresponding to a cross-sectional view taken along line X-X

FIG. 10 illustrates the configuration of still another embodiment of the present invention corresponding to a cross-sectional view taken along line X-X.

### BEST MODE

Hereinafter, preferred embodiments of the present invention are described in detail with reference to the accompanying drawings, but the present invention is not limited to the embodiments. For reference, in this description, the same numbers refer to substantially the same elements, and, under these rules, descriptions may be made by citing contents described in other drawings. In addition, contents determined to be obvious to those of skill in the art or repeated contents may be omitted.

A substrate chuck 100 according to an embodiment of the present invention includes a surface plate 110 having space portions 112 as an empty space open upward over partial areas of the surface plate 110 and having a flat top surface; a chucking film 120 made of a flexible material capable of elastic deformation with respect to a mounting area where the substrate W is mounted and installed to cover an upper surface of the surface plate; a driving motor 130 configured to rotate the surface plate 110; a monitoring sensor 140 configured to monitor elastic deformation of the chucking film; a support 150 configured to support the surface plate 110 rotated by the driving motor 130; and a pressure adjuster 160 configured to supply negative pressure V1 or positive pressure P1 to the space parts 112.

Here, the substrate W includes various types of substrates and includes both wafers used for manufacturing semiconductor packages and substrates made of materials such as glass.

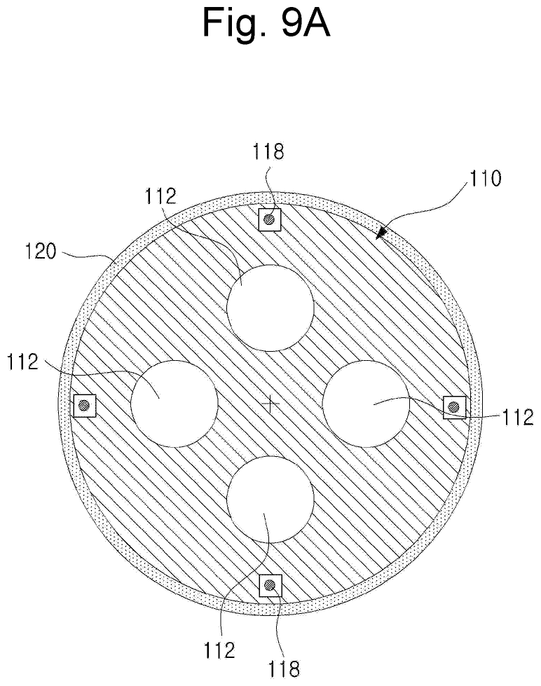

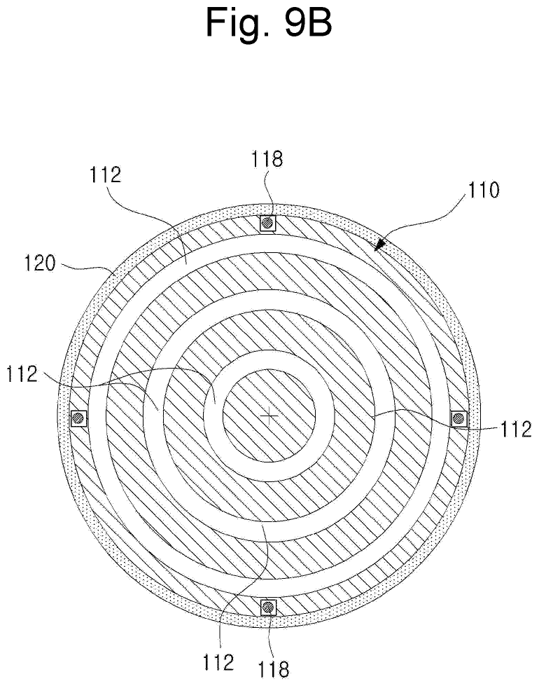

The surface plate 110 is rotatably installed around a rotation axis 91 in the direction of gravity by means of a rotational support 155, disposed as a bearing or the like, between the surface plate 110 and the support 150 and has a circular cross-section as shown in FIG. 9A.

An upper surface of the surface plate 110 is formed in a flat surface shape to be installed in the mounting area, where the substrate W is to be mounted, in close contact with a bottom surface of the chucking film 120. The surface plate 110 is preferably made of a material with high rigidity, and may be made of, for example, a metal material such as steel.

To allow the chucking film 120 to undergo downward convex elastic deformation, the upper surface of the surface plate 110 is provided with the space parts 112 formed as empty spaces on a lower side of the chucking film 120. Preferably, the plural space parts 112 are formed in a cross-section shape in a partial area of the substrate W and are symmetrically arranged around the rotation axis located at the center of the chucking film 120 such that a plurality of positions of the substrate W can be gripped. As shown in FIG. 9A, the space parts 112 may be formed at multiple locations to be spaced apart from each other, and as shown in FIG. 9B, the space parts 112 may be formed in a shape of a plurality of rings.

In the embodiments illustrated in the drawings, the space parts 112 are not formed at the position of the rotation axis 91. However, according to another embodiment of the present invention, another space part 112 may be formed at the position of the rotation axis 91.

Below the gravity direction of the space parts 112, an air chamber 116 communicating with the plural space parts is formed in a transverse direction perpendicular to the rotation axis. The air chamber 116 has a wide open cross-section. Accordingly, the pressure of the plural space parts 112 may be uniformly controlled by adjusting the pressure of the air chamber 116.

In addition, a pneumatic passage 111 extends from the pressure adjuster 160 to the air chamber 116 along the rotation axis 91 of the surface plate 110. As the pneumatic passage 111 is formed along the rotation axis 91 of the surface plate 110, it becomes easy to accurately transmit an intended air pressure to the space parts 112 even when the surface plate 110 rotates. Although not shown in the drawings, according to another embodiment of the present invention, the pneumatic passage 111 may be disposed at a position radially spaced apart from the rotation axis 91 of the surface plate 110, and a part of the pneumatic passage 111 may be disposed in a form of penetrating the rotation axis 91 of the surface plate 110.

The chucking film 120 is formed to cover an entirety of the flat upper surface of the surface plate 110 which is a mounting area on which the substrate W is mounted. The chucking film 120 does not have a through hole and is formed of a flexible material capable of elastic deformation and an easily adherable material. For example, the chucking film 120 may be formed of a material such as rubber or polyurethane.

The chucking film 120 may be fixed to the surface plate 110 in various ways, and as shown in the drawings, the radial end of the chucking film 120 may be fixed in a state of being fitted while wrapping the outer circumferential side of the surface plate 110. The chucking film 120 may be firmly fixed to the surface plate 110 using fixing bolts.

The driving motor 130 is installed to rotatably drive the surface plate 110. An installation method of the driving motor 130 may be determined in various ways and, below the gravity direction of the surface plate 110 as shown in the drawings, a rotor 132 of the driving motor 130 and the bottom surface of the surface plate 110 may be connected to each other. Although not shown in the drawings, according to another embodiment of the present invention, the rotor of the driving motor 130 may be connected to the outer circumferential surface of the surface plate 110 and may rotatably drive the surface plate 110 via a power transmission means such as a belt, chain, or gear.

Since a casing 134 including a stator 133 of the driving motor 130 is installed in a non-rotating state, the casing 134 may be fixed to the support 150 in a non-rotating state using a bracket 138. In addition, since the center of the rotor of the driving motor 130 is arranged to coincide with the rotation axis 91 of the surface plate 110 and the pneumatic passage 111 is provided along the rotation axis 91 of the surface plate 110, the rotor 132 of the driving motor 130 is provided with a hollow part 132a communicating with the pneumatic passage 111.

A rotary seal 139 is installed between a lower part of the rotor 132 in the direction of gravity and the casing 134, and a stopper 134a is installed in a lower part of the casing 134 communicating with the pneumatic passage 111. The stopper 134a blocks the pneumatic passage 111 from the outside air and is coupled to a pneumatic pipe of the pressure adjuster 160.

The pressure adjuster 160 controls the pressure of the space parts 112 via the hollow part 132a of the driving motor 130, the pneumatic passage 111 and the air chamber 116.

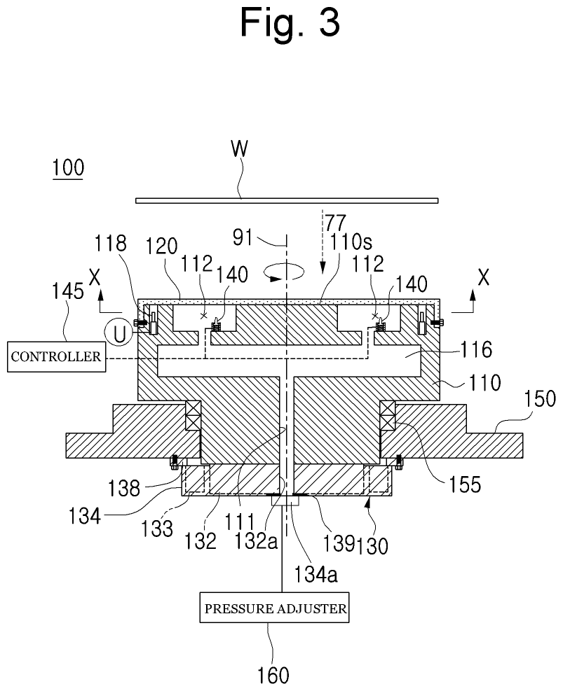

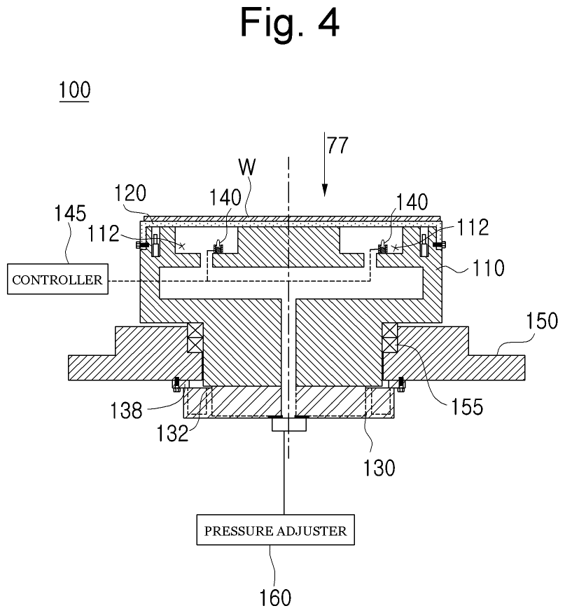

Specifically, when the substrate W is placed (77) on an upper surface of the chucking film 120 of the substrate chuck 100 (FIGS. 3 and 4), the pressure adjuster 160 sucks air in the pneumatic passage 111 and the air chamber 116 such that the pressure in the air chamber 116 reaches a predetermined negative pressure V1. Since the plural space parts 112 are in communication with the air chamber 116, the pressure of the plural space parts 112 is also in the same state as the negative pressure V1 of the air chamber 116.

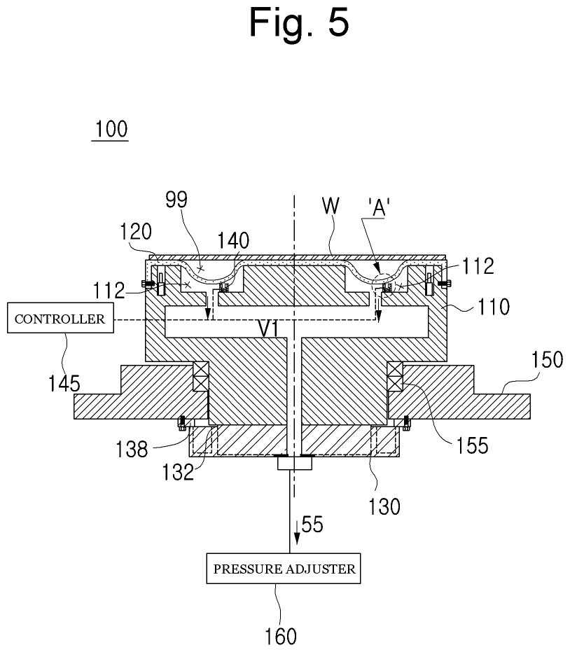

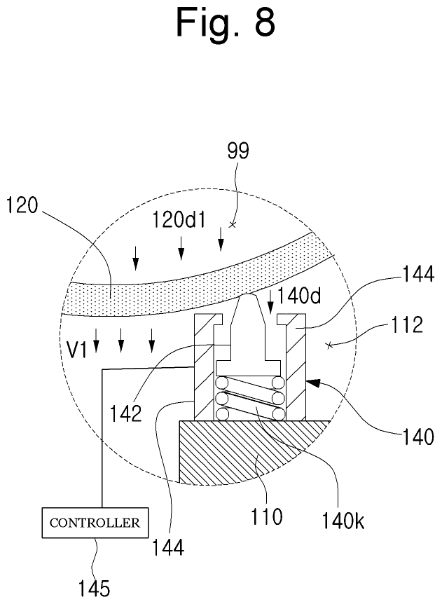

Accordingly, a part, which covers the space parts 112, of the chucking film 120 covering the flat upper surface 110s of the surface plate 110 in close contact therewith is elastically deformed in a downward convex shape (120d1) as shown in FIGS. 5 and 8. In contrast, since the substrate W, which has much higher bending rigidity than the chucking film 120, does not undergo downward bending deformation, a vacuum space 99 is formed at a position, where the space parts 112 occupies, between the substrate W and the chucking film 120.

Accordingly, since the vacuum 99 is formed between the substrate W and the chucking film 120 while the chucking film 120 is elastically deformed downward in a portion corresponding to the upper side of the space parts 112 of the surface plate 110, the substrate W is positioned at and firmly fixed to the chucking film 120 by the vacuum space 99 formed between the chucking film 120 and the substrate W. At the same time, since the chucking film 120 completely covers the flat upper surface 110s of the surface plate without holes, an advantageous effect of completely excluding the possibility of liquid inflow into the substrate chuck 100 may be obtained.

Meanwhile, the monitoring sensor 140 is installed in the space parts 112 of the surface plate 110 to detect whether the displacement of the chucking film 120 convex downward to hold the substrate W reaches a predetermined value.

In other words, to reliably grip the substrate W, it is necessary that the vacuum space 99 formed in each of the space parts 112 is sufficiently large. For this, when the elastic deformation (120d1) in which the chucking film 120 is convex downward occurs in the space parts 112 by the negative pressure V1 from the pressure adjuster 160, the monitoring sensor 140 installed in the space parts 112 detects whether the downward convex displacement of the chucking film 120 reaches a predetermined value as shown in FIG. 8.

Here, the monitoring sensor 140 may include a sensing pin 142 that is elastically supported by a spring 140k installed inside a sensor box 144 and is movable in an up-down direction in contact with the bottom surface of the chucking film 120. Accordingly, when suction pressure is applied to the space parts 112 so that the chucking film 120 undergoes the downward convex deformation (120d1), the chucking film 120 contacts the top of the sensing pin 142 and moves downward (140d) the sensing pin 142. A controller 145 determines based on a downward movement amount of the sensing pin 142 whether the downward convex displacement amount of the chucking film 120 reaches a predetermined positive displacement amount and controls the magnitude of the negative pressure V1 applied by the pressure adjuster 160. Meanwhile, the monitoring sensor 140 may be applied in the form of a non-contact sensor using a laser or the like in addition to a sensor supported by a spring, and according to another embodiment of the present invention, a sensor having another known configuration capable of measuring displacement may be applied.

Accordingly, when the magnitude of the negative pressure V1 acting in each of the space parts 112 is adjusted by the pressure adjuster 160, the amount of downward bending deformation of the chucking film 120 in the space parts 112 is sensed by the monitoring sensor 140, and, when it is sensed by the monitoring sensor 140 that the amount of downward bending deformation of the chucking film 120 in the space parts 112 does not reach a predetermined value, the controller 145 controls the size of an absolute value of the negative pressure, applied by the pressure adjuster 160, to be larger so that an advantageous effect of reliably realizing the fixed state of the substrate W to the chucking film can be obtained.

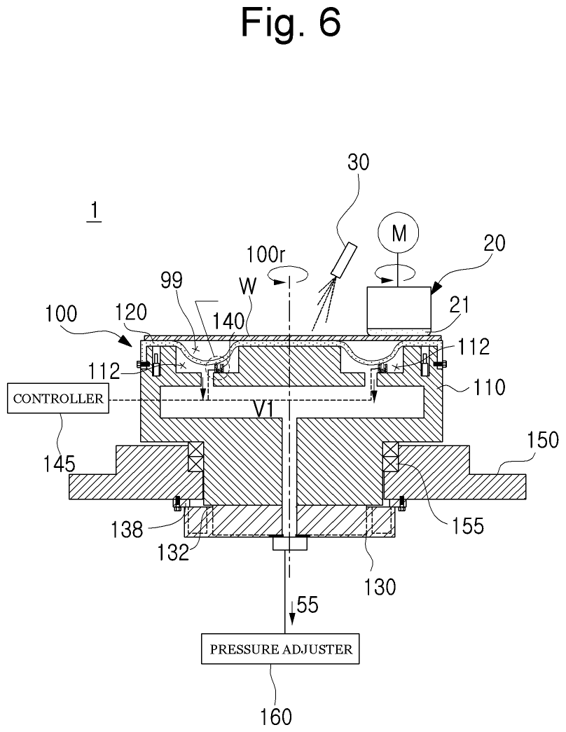

As shown in FIG. 6, a substrate scrubbing apparatus 1 according to an embodiment of the present invention may further include a scrubbing unit 20 configured to scrub the upper surface of the substrate W with the pad 21 in a state in which the substrate W is adsorbed and fixed, by the vacuum space 99, to the upper surface of the substrate chuck 100 configured as described above; and a fluid supplier 30 configured to spray a slurry or a cleaning liquid to assist the scrubbing process.

Accordingly, since there is no possibility that the liquid supplied from the fluid supplier 30 penetrates into the substrate chuck 100 and, at the same time, a substrate may be reliably fixed to the substrate chuck 100, a reliable operation may be implemented even if a conventional gas-liquid separator is not provided, and manpower and costs for maintenance and repair of the substrate scrubbing apparatus 1 may be reduced.

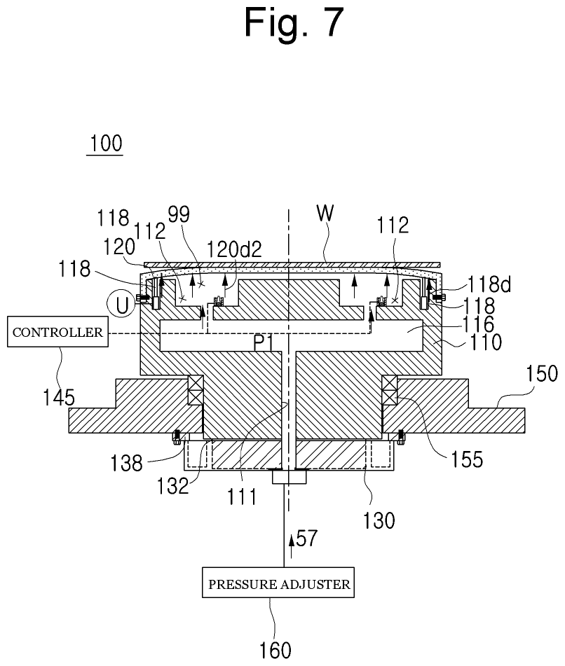

Meanwhile, when a treatment process such as a substrate scrubbing process is finished, the pressure adjuster 160 supplies pneumatic pressure through the pneumatic passage 111 as shown in FIG. 7 such that the pressure of the space parts 112 becomes the positive pressure P1.

Accordingly, as the gas expands in the space parts 112, the chucking film 120 located on the space parts 112 is elastically deformed (120d2) so that it becomes convex upward. Therefore, the substrate W, whose bottom surface was in a state of being in close contact with the upper surface of the chucking film 120, becomes convex upward as a whole, so that the contact state between the substrate W and the chucking film 120 is released, resulting in separation of the substrate W from the chucking film 120.

Meanwhile, as shown in FIGS. 7, 9A and 9B, a plurality of lift pins 118 are provided at positions spaced apart from each other at the edge of the surface plate 110 along a circumferential direction, and the chucking film 120 is lifted by the lift pins 118 upward when the substrate treatment process is finished. This may be performed separately or simultaneously with separating the substrate W from the chucking film 120 through elastic deformation wherein the positive pressure P1 is supplied by the pressure adjuster 160 and the chucking film 120 becomes convex upward. As the lift pins 118 are moved or extended upward by an operation part U, the edge of the chucking film 120 is pushed upward so that the substrate W is more easily separated from the chucking film 120.

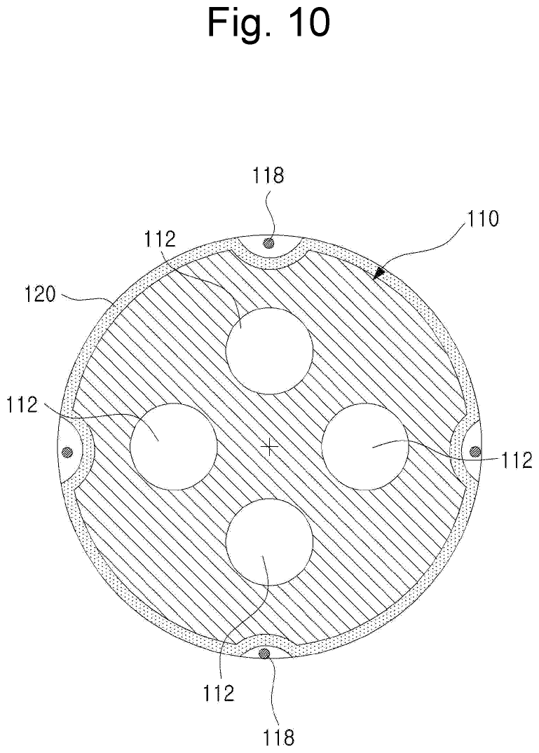

Although FIGS. 7, 9A and 9B illustrate the configuration wherein the lift pins 118 push the chucking film 120 upward, the lift pins 118 may be disposed outside the chucking film 120 such that the upper ends of the lift pins 118 directly lift the substrate W upward as shown in FIG. 10. Accordingly, the action of separating the substrate W from the chucking film 120 may be more reliably performed.

By the present invention configured as described above, the upper surface 110s of the substrate chuck 100, on which the substrate W is seated, is entirely covered with the chucking film 120 made of a flexible material capable of elastic deformation, and suction pressure is applied to the plural space parts 112 on the lower side of the chucking film 120, thereby forming the vacuum space 99 between the chucking film 120 and the substrate W to grip the substrate W. Therefore, the liquid used during the treatment process may be fundamentally prevented from entering the inside of the substrate chuck 100.

Although the present invention has been illustratively described through preferred embodiments, the present invention is not limited to such specific embodiments, and modification, change, or improvement may be made in various forms within the technical idea presented in the present invention, specifically within the scope described in the claims.

[Description of Symbols]

| | |
|---|---|
| W: substrate | 1: substrate scrubbing apparatus |
| 100: substrate chuck | 110: surface plate |
| 111: pneumatic passage | 112: space part |
| 116: air chamber | 118: lift pin |
| 120: chucking film | 130: driving motor |
| 139: rotary seal | 140: monitoring sensor |
| 150: support | 160: pressure adjuster |

What is claimed is:

1. A substrate chuck for fixing a substrate in a state in which the substrate is fixed
to an upper surface of the substrate chuck, the substrate chuck comprising:
a surface plate;
a chucking film installed in a form of covering an upper surface of the surface plate with a flexible material capable of elastic deformation in an area where the substrate is mounted; and
a pressure adjuster configured to supply suction pressure to a lower part of the chucking film.

2. The substrate chuck according to claim 1, wherein, by the pressure adjuster, a vacuum is formed between the substrate and the chucking film as at least a partial region of the chucking film is elastically deformed downward, thereby fixing the substrate.

3. The substrate chuck according to claim 2, wherein a space part forming an empty space on a bottom surface of the chucking film is provided on an upper surface of the surface plate and the pressure adjuster applies suction pressure to the space part so that the chucking film is elastically deformed downward in the space part.

4. The substrate chuck according to claim 3, wherein the space part is formed of a plurality of space parts.

5. The substrate chuck according to claim 4, wherein the space parts are formed in a form of a plurality of concentric circles.

6. The substrate chuck according to claim 4, wherein an air chamber communicating with the plural space parts is formed in the surface plate.

7. The substrate chuck according to claim 1, further comprising a driving motor for rotating the surface plate.

8. The substrate chuck according to claim 7, wherein a pneumatic passage extending in a form of penetrating at least a part of a rotation center of the surface plate from the pressure adjuster is formed in the surface plate.

9. The substrate chuck according to claim 8, wherein a rotary seal is provided between an end of the pneumatic passage of the surface plate and the driving motor so that the pneumatic passage is kept in a state of being sealed from outside.

10. The substrate chuck according to claim 4, wherein the space parts are symmetrically arranged with respect to a center of the chucking film.

11. The substrate chuck according to claim 1, wherein the pressure adjuster applies a positive pressure to separate the substrate from the chucking film by making the chucking film convex upward.

12. The substrate chuck according to claim 1, wherein an edge of the surface plate is provided with a plurality of lift pins for lifting the chucking film upward.

13. The substrate chuck according to claim 3, wherein the space parts are provided with a monitoring sensor for sensing downward convex displacement of the chucking film.

14. The substrate chuck according to claim 13, wherein the monitoring sensor is elastically supported by a spring and comes into contact with a bottom surface of the chucking film to sense a predetermined positive displacement amount.

15. A substrate scrubbing apparatus, comprising:
the substrate chuck according to claim 1; and
a scrubbing unit mounted on an upper surface of the chucking film of the substrate chuck and configured to scrub an upper surface of a positioned and fixed substrate.
